(19) United States
(12) Patent Application Publication
(10) Pub. No.: US 2025/0151523 A1
(43) Pub. Date: May 8, 2025

(54) DISPLAY PANEL

(71) Applicant: Samsung Display Co., Ltd., Yongin-si (KR)

(72) Inventors: SUNGJAE MOON, Yongin-si (KR); YOUNGHOON YOO, Yongin-si (KR); JIN-WON LEE, Yongin-si (KR)

(21) Appl. No.: 18/915,227

(22) Filed: Oct. 14, 2024

(30) Foreign Application Priority Data
Nov. 7, 2023 (KR) 10-2023-0152697

(51) Int. Cl. H10K 59/121; H10K 59/124; H10K 59/126; H10K 59/131

(52) U.S. Cl. CPC H10K 59/1216; H10K 59/1213; H10K 59/124; H10K 59/126; H10K 59/131

(57) ABSTRACT

A display panel is proved. The display panel including a base layer, a light blocking pattern on the base layer, a semiconductor pattern not overlapping the light blocking pattern, a lower capacitor pattern including a first portion overlapping the light blocking pattern and a second portion protruding in a first direction from the first portion and overlapping the semiconductor pattern, an upper capacitor pattern overlapping the lower capacitor pattern, and a light-emitting element connected to the semiconductor pattern. The light blocking pattern includes a lower surface facing the base layer, an upper surface opposed to the lower surface, and a side surface connecting the lower surface and the upper surface. The upper capacitor pattern faces the semiconductor pattern in the first direction.

### CROSS-REFERENCE TO RELATED APPLICATIONS

The present application claims priority to and the benefit of Korean Patent Application No. 10-2023-0152697, filed on Nov. 7, 2023, in the Korean Intellectual Property Office, the entire disclosure of which is incorporated by reference herein.

### BACKGROUND

### 1. Field

The present disclosure herein relates to a display panel, and more particularly, to a display panel including a circuit element having improved reliability.

### 2. Description of the Related Art

A display panel includes a plurality of pixels and a driving circuit (e.g., a scan driving circuit and a data driving circuit) for controlling the plurality of pixels. Each of the plurality of pixels includes a display element and a pixel driving circuit for controlling the display element. The pixel driving circuit may include a plurality of transistors connected to each other and at least one capacitor.

### SUMMARY

The present disclosure provides a display panel having improved display quality. More specifically, the present disclosure provides a display panel having alleviated bright spot occurrence.

One or more embodiments of the present disclosure provide a display panel including a base layer, a light blocking pattern on the base layer, a semiconductor pattern not overlapping the light blocking pattern, a lower capacitor pattern including a first portion overlapping the light blocking pattern and a second portion protruding in a first direction from the first portion and overlapping the semiconductor pattern, an upper capacitor pattern overlapping the lower capacitor pattern, and a light-emitting element connected to the semiconductor pattern, wherein the light blocking pattern includes a lower surface facing the base layer, an upper surface opposed to the lower surface, and a side surface connecting the lower surface and the upper surface, and the upper capacitor pattern overlaps the side surface facing the semiconductor pattern in the first direction.

In one or more embodiments, an angle between the lower surface and the side surface of the light blocking pattern may be about 60 degrees to about 80 degrees.

In one or more embodiments, the display panel may include a first insulating layer on the base layer and covering the light blocking pattern, a second insulating layer on the first insulating layer and covering the semiconductor pattern, a third insulating layer on the second insulating layer and covering the lower capacitor pattern, a fourth insulating layer on the third insulating layer and covering the upper capacitor pattern, and a fifth insulating layer on the fourth insulating layer and including an organic material.

In one or more embodiments, the display panel may further include a bridge pattern overlapping the semiconductor pattern and the second portion of the lower capacitor pattern, wherein one end of the bridge pattern may be connected to the semiconductor pattern through a first contact hole passing through the second and third insulating layers, and an other end of the bridge pattern may be connected to the second portion of the lower capacitor pattern through a second contact hole passing through the third insulating layer.

In one or more embodiments, the first insulating layer, the second insulating layer, the lower capacitor pattern, the third insulating layer, the upper capacitor pattern, and the fourth insulating layer may be on the side surface of the light blocking pattern facing the semiconductor pattern in the first direction.

In one or more embodiments, a portion, of the upper capacitor pattern, overlapping the side surface of the light blocking pattern facing the semiconductor pattern in the first direction may be inclined at an angle corresponding to an inclined angle of the side surface.

In one or more embodiments, the display panel may include a first power line, a scan line, a sensing line, which extend along the first direction and are spaced from each other along a second direction crossing the first direction, and a data line which extends along the second direction, wherein the light blocking pattern may be located between the scan line and the sensing line.

In one or more embodiments, the scan line may further include a scan pattern protruding in the second direction, and the scan pattern may overlap the semiconductor pattern.

In one or more embodiments, a portion of the scan pattern overlapping the semiconductor pattern may include a gate of a transistor including the semiconductor pattern.

In one or more embodiments, the scan pattern may be on the second insulating layer and covered by the third insulating layer, and a portion of the scan pattern may be connected to the scan line through a contact hole in the third insulating layer.

In one or more embodiments, the display panel may further include a data pattern having one end overlapping the semiconductor pattern and an other end overlapping the data line, wherein the one end of the data pattern may be connected to the semiconductor pattern through a third contact hole passing through the second and third insulating layers, and the other end of the data pattern may be connected to the data line through a fourth contact hole passing through the first to third insulating layers.

In one or more embodiments, the light-emitting element may include a first electrode on the fifth insulating layer, a second electrode, and a common layer located between the first electrode and the second electrode, and the first electrode may be connected to the upper capacitor pattern through a fifth contact hole passing through the fourth insulating layer and a sixth contact hole passing through the fifth insulating layer and overlapping the fifth contact hole.

In one or more embodiments, the display panel may further include an encapsulation layer on the light-emitting element and including inorganic layers and an organic layer between the inorganic layers.

In one or more embodiments, the display panel may further include a light control layer on the encapsulation layer and including a color control pattern including quantum dots and a color filter pattern on the color control pattern.

In one or more embodiments of the present disclosure, a display panel includes a base layer, a light blocking pattern on the base layer, a data line spaced from the light blocking pattern along a first direction and extending along a second direction crossing the first direction, a capacitor including a lower capacitor pattern overlapping the light blocking pattern and an upper capacitor pattern overlapping the lower capacitor pattern, and a pixel including a light-emitting element and a first transistor, a second transistor, and a third transistor, each of the first to third transistors including a semiconductor pattern, wherein the semiconductor pattern included in the second transistor is connected to the data line, and a side surface of the light blocking pattern facing the semiconductor pattern in the second transistor in the first direction is covered by the upper capacitor pattern.

In one or more embodiments, an angle between the base layer and the side surface of the light blocking pattern may be about 60 degrees to about 80 degrees.

In one or more embodiments, the display panel may include a first power line, a scan line, and a sensing line, which extend along the first direction and are spaced from each other along the second direction crossing the first direction, and an initial line which extends along the second direction, wherein the light blocking pattern may be located between the scan line and the sensing line.

In one or more embodiments, the semiconductor pattern in the first transistor may be connected to the first power line.

In one or more embodiments, the semiconductor pattern included in the third transistor may be connected to the initial line.

In one or more embodiments, a portion, of the upper capacitor pattern, overlapping the side surface of the light blocking pattern, may be inclined at a predetermined angle.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1A is a perspective view of a display panel according to one or more embodiments of the present disclosure;

FIG. 1B is a perspective view of a curved display panel according to one or more embodiments of the present disclosure;

FIG. 2A is a cross-sectional view of a display panel according to one or more embodiments of the present disclosure;

FIG. 2B is a plan view of a display panel according to one or more embodiments of the present disclosure;

FIG. 3 is an equivalent circuit diagram of a pixel according to one or more embodiments of the present disclosure;

FIG. 4 is an enlarged plan view of a display region according to one or more embodiments of the present disclosure;

FIG. 5A is a plan view illustrating that conductive patterns included in a pixel unit according to one or more embodiments of the present disclosure are stacked in a stacking order;

FIG. 5B is a cross-sectional view taken along the line I-I′ in FIG. 5A;

FIGS. 6A-6I are plan views illustrating, for each layer, a stacking order of conductive patterns included in a pixel unit according to one or more embodiments of the present disclosure;

FIG. 7A is an enlarged plan view of one region of a pixel unit according to one or more embodiments of the present disclosure;

FIG. 7B is a cross-sectional view taken along the line III-III′ in FIG. 7A;

FIG. 8A is a plan view of a comparative example; and

FIG. 8B is a cross-sectional view taken along the line IV-IV′ in FIG. 8A.

### DETAILED DESCRIPTION

In the present disclosure, it will be understood that when an element (or a region, a layer, a portion, and/or the like) is referred to as being “on”, “connected to” or “coupled to” another element, it may be directly disposed on, connected or coupled to the other element, or an intervening element may be disposed therebetween.

Like reference numerals or symbols refer to like elements throughout. Also, in the drawings, the thicknesses, ratios, and dimensions of the elements are exaggerated for effective description of the technical contents. The term “and/or” includes all of one or more combinations which the associated elements may define.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the spirit or scope of the present disclosure. The singular forms include the plural forms as well unless the context clearly indicates otherwise.

Also, terms such as “below”, “lower”, “above”, “upper” are used to describe the relationships of the elements illustrated in the drawings. These terms have relative concepts and are described on the basis of the directions indicated in the drawings.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, and/or combinations thereof.

Unless otherwise defined, all terms (including technical and scientific terms) used herein have the same meaning as commonly understood by one of ordinary skill in the art to which the present disclosure belongs. In addition, terms, such as those defined in commonly used dictionaries, should be interpreted as having a meaning that is consistent with their meaning in the context of the relevant art and should not be interpreted in an overly idealized or overly formal sense unless expressly so defined herein.

Hereinafter, embodiments of the present disclosure will be described with reference to the accompanying drawings.

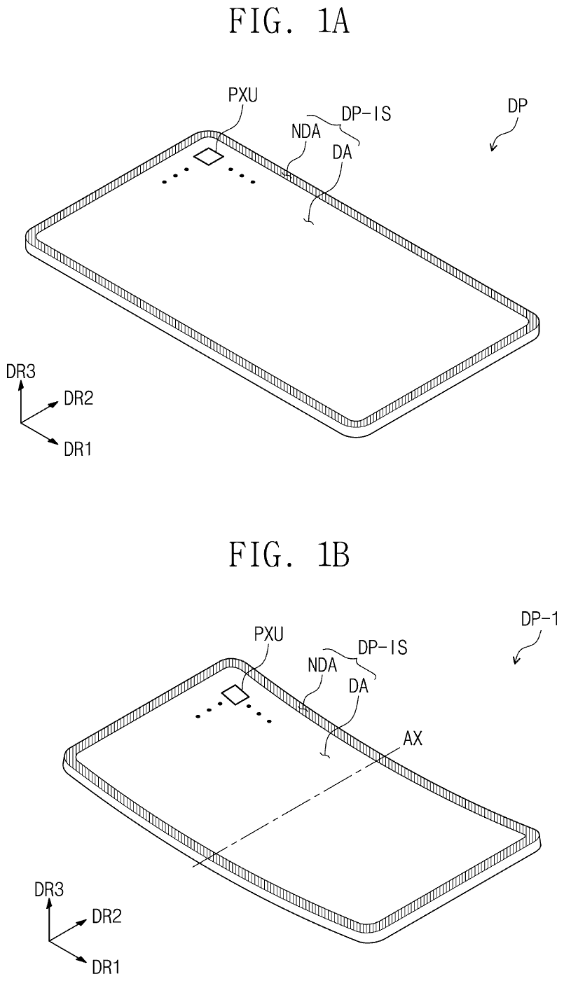

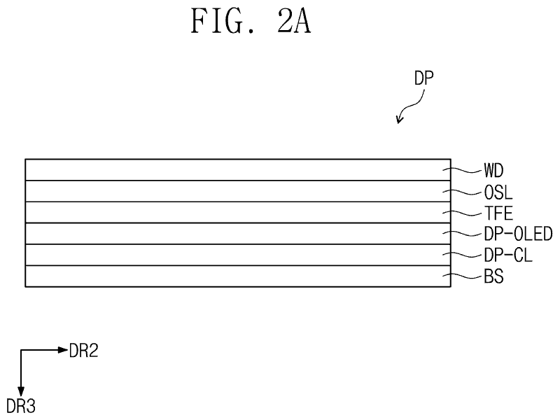

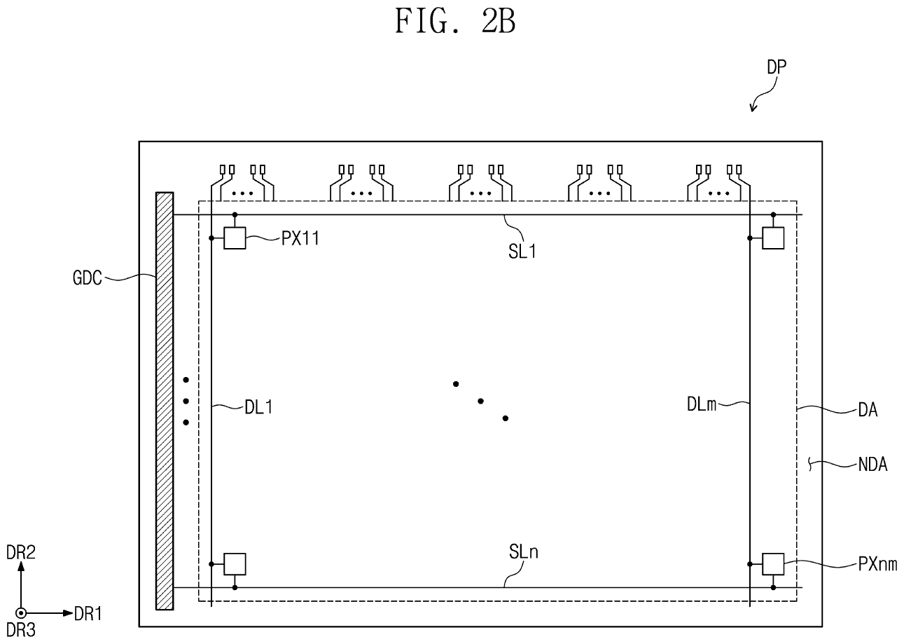

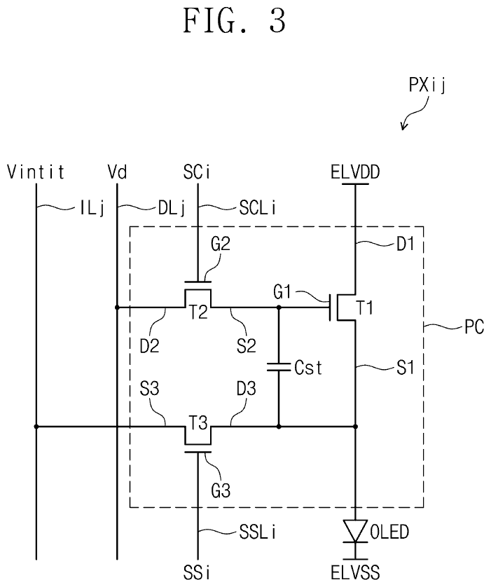

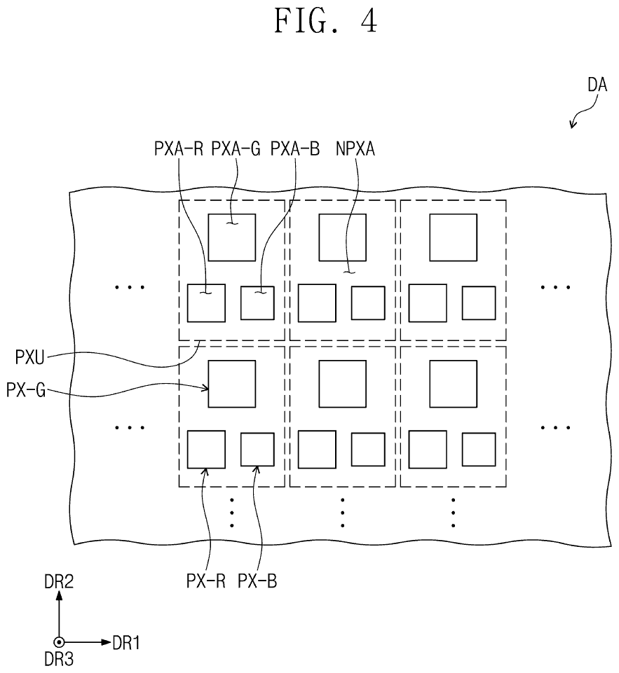

FIG. 1A is a perspective view of a display panel according to one or more embodiments of the present disclosure. FIG. 1B is a perspective view of a curved display panel according to one or more embodiments of the present disclosure. FIG. 2A is a cross-sectional view of a display panel according to one or more embodiments of the present disclosure. FIG. 2B is a plan view of a display panel according to one or more embodiments of the present disclosure. FIG. 3 is an equivalent circuit diagram of a pixel according to one or more embodiments of the present disclosure. FIG. 4 is an enlarged plan view of a display region according to one or more embodiments of the present disclosure.

A display panel DP or DP-1 illustrated in FIG. 1A or FIG. 1B may be a light-emitting display panel and may be a liquid crystal display panel, an electrophoretic display panel, a microelectromechanical system (MEMS) display panel, an electrowetting display panel, an organic light-emitting display panel, an inorganic light-emitting display panel, and/or a quantum dot display panel. In addition, the display panel DP or DP-1 according to one or more embodiments of the present disclosure may include an ultrasmall light-emitting element. For example, the display panel DP or DP-1 may include a micro-LED element and/or a nano-LED element, but the present disclosure is not particularly limited thereto.

Referring to FIG. 1A, the display panel DP may display an image through a display surface DP-IS. An upper surface of a member disposed on the uppermost side of the display panel DP may be defined as the display surface DP-IS. According to one or more embodiments, an upper surface of a window panel WD illustrated in FIG. 2A may be provided as the display surface DP-IS of the display panel DP.

The display surface DP-IS may be parallel to a plane defined by a first direction DR1 and a second direction DR2. A normal direction of the display surface DP-IS that is a thickness direction of the display panel DP indicates a third direction DR3. A front surface (or an upper surface) and a rear surface (or a lower surface) of each layer or unit to be described below are distinguished from each other on the basis of the third direction DR3.

The display panel DP may include a display region DA and a non-display region NDA disposed along an edge or a periphery of the display area DA. A light-emitting layer of a pixel PXnm (see FIG. 2B) is disposed in the display region DA, and the light-emitting layer of the pixel PXnm (see FIG. 2B) is not disposed in the non-display region NDA. The non-display region NDA is defined along an edge of the display surface DP-IS. The non-display region NDA may be around (e.g., may surround) the display region DA. In one or more embodiments, the non-display region NDA may be omitted or disposed on only one side of the display region DA.

Referring to FIG. 1B, the display panel DP-1 according to one or more embodiments may be curved along a first direction DR1 with respect to a virtual axis AX extending in a second direction DR2. However, the present disclosure is not limited thereto, and an axis may extend in the first direction DR1, or the display panel DP-1 may be curved with respect to a plurality of axes extending in different directions.

The display panel DP or DP-1 according to one or more embodiments may be a rollable display panel, a foldable display panel, and/or a slidable display panel. Here, the display panel DP or DP-1 may have a flexible property and may be capable of folding and/or rolling while being installed on a display device. Accordingly, the display panel DP or DP-1 may also include a curved display surface and/or a stereoscopic display surface DP-IS. The stereoscopic display surface DP-IS may also include a plurality of display regions which indicate different directions.

FIG. 1A and FIG. 1B illustrate that pixel units PXU are arranged along the first direction DR1 and the second direction DR2 in display regions DA. One pixel unit PXU may be a region where pixels that provide source light are disposed. An emission area, shape, and/or arrangement of each of the pixels included in a pixel unit PXU are not limited to any one emission area, shape, and/or arrangement. For example, respective emission areas of the pixels included in the pixel unit PXU may be different from each other. In addition, light-emitting regions may each have a circular and/or polygonal shape on a plane.

Referring to FIG. 2A and FIG. 2B, a display panel DP according to one or more embodiments includes a base layer BS, a circuit element layer DP-CL disposed on the base layer BS, a display element layer DP-OLED, an encapsulation layer TFE, a light control layer OSL, and a window panel WD. The display panel DP may further include functional layers such as an anti-reflective layer and/or a refractive index adjusting layer. The circuit element layer DP-CL includes at least a plurality of insulating layers and a circuit element. Insulating layers to be described below may include an organic layer and/or an inorganic layer.

The base layer BS may include a synthetic resin film. The synthetic resin film may include a thermosetting resin. In particular, the synthetic resin film may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and/or a perylene-based resin. In addition, the base layer BS may include a glass substrate, a metal substrate, an organic/inorganic composite material substrate, and/or the like.

In the circuit element layer DP-CL, an insulating layer, a semiconductor layer, and/or a conductive layer are formed through a process such as coating or deposition. Then, the insulating layer, the semiconductor layer, and/or the conductive layer may be selectively patterned through photolithography and/or etching processes. Through such processes, a semiconductor pattern, a conductive pattern, a signal line, etc., are formed. Patterns disposed on the same layer may be formed through the same process.

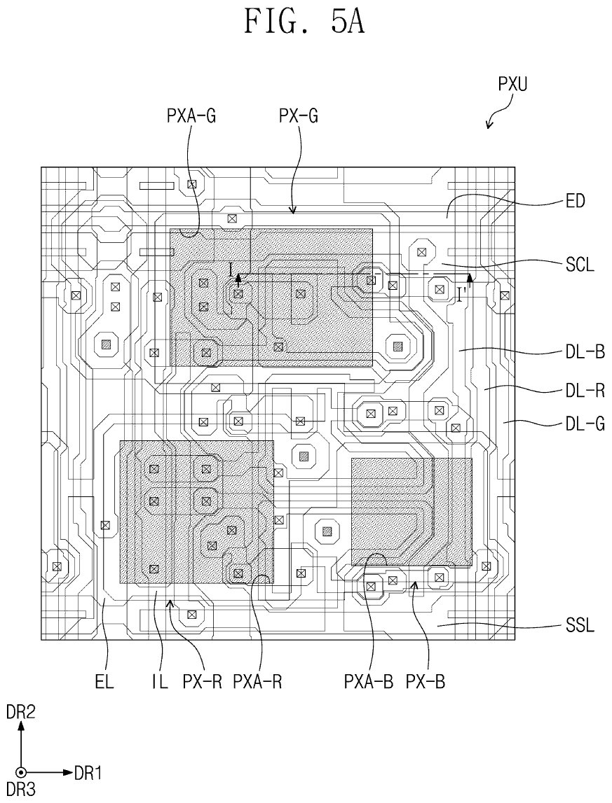

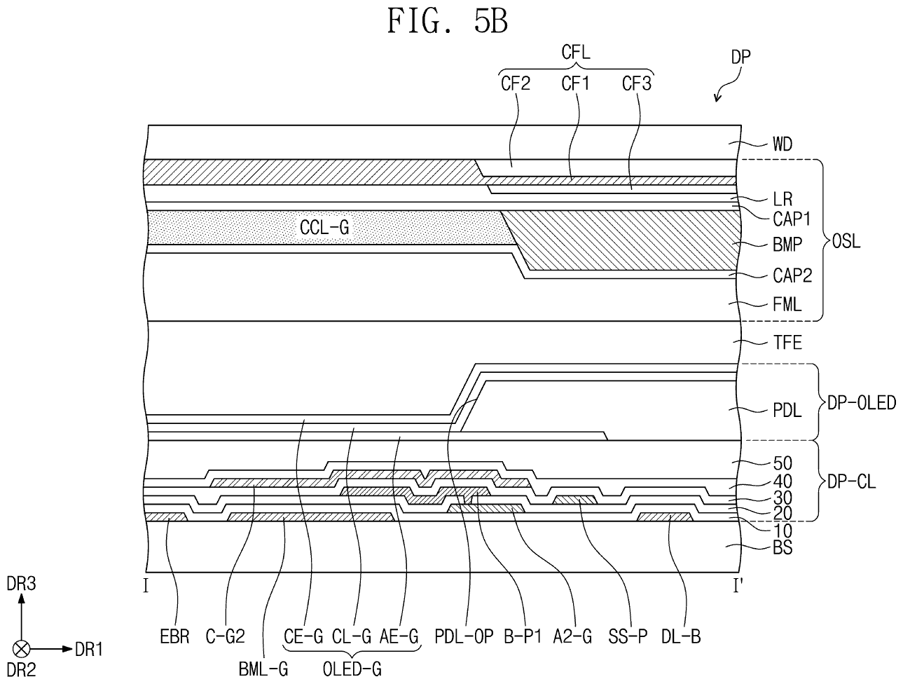

The circuit element layer DP-CL includes a signal line or a driving circuit, which constitutes a pixel. The display element layer DP-OLED may include a pixel-defining film PDL (see FIG. 5B) and a light-emitting element OLED-G (see FIG. 5B) included in each of pixels.

The encapsulation layer TFE may be disposed on the display element layer DP-OLED to protect the light-emitting element OLED. The encapsulation layer TFE may include inorganic layers and an organic layer disposed between the inorganic layers. The inorganic layers may protect the light-emitting element OLED from moisture and oxygen, and the organic layer may protect the light-emitting element OLED from foreign substances such as dust particles.

The light control layer OSL may include light control patterns capable of converting an optical property of source light generated from a light-emitting element. The light control patterns may include quantum dots, and may include color filter patterns to allow light transmitted through the light control patterns to be selectively transmitted.

The window panel WD may be disposed in an upper portion of the display panel DP and may transmit, to the outside, an image provided from the display panel DP. In the window panel WD, the display region DA and the non-display region NDA of the display surface DP-IS may be distinguished from each other as illustrated in FIG. 1A. A boundary between the display region DA and the non-display region NDA may be defined by a bezel pattern which is disposed below the window panel WD and absorbs light.

The window panel WD may include a base layer and functional layers disposed on the base layer. The functional layers may include a protective layer, an anti-fingerprint layer, etc. The base layer of the window panel WD may include glass, sapphire, plastic, and/or the like. According to one or more embodiments, components included in the light control layer OSL may be disposed on a rear surface of the window panel WD. The light control layer OSL disposed on the window panel WD may be coupled to the encapsulation layer TFE with a suitable space (e.g., a predetermined space) therebetween.

FIG. 2B illustrates a planar arrangement relationship of signal lines SL1 to SLn and DL1 to DLm and pixels PX11 to PXnm, which are included in a display panel DP. The signal lines SL1 to SLn and DL1 to DLm may include a plurality of scan lines SL1 to SLn and a plurality of data lines DL1 to DLm.

The pixels PX11 to PXnm may be disposed in a display region DA. Each of the pixels PX11 to PXnm is connected to a corresponding scan line from among the plurality of scan lines SL1 to SLn and a corresponding data line from among the plurality of data lines DL1 to DLm. Each of the pixels PX11 to PXnm may include a pixel driving circuit and a light-emitting element. Various types of signal lines may be further included in the display panel DP according to the configuration of a pixel driving circuit of the pixels PX11 to PXnm.

A gate driving circuit GDC may be disposed in a non-display region NDA. The gate driving circuit GDC may be integrated into the display panel DP through an oxide silicon gate (OSG) driver circuit process or an amorphous silicon gate (ASG) driver circuit process.

FIG. 3 illustrates, as an example, a circuit diagram of one pixel PXij from among the pixels PX11 to PXnm.

The pixel PXij may include a pixel circuit PC and a light-emitting element OLED. The pixel circuit PC may include a plurality of transistors T1 to T3 and a capacitor Cst.

The plurality of transistors T1 to T3 may be formed through a low temperature polycrystalline silicon (LTPS) process or a low temperature polycrystalline oxide (LTPO) process. Each of first to third transistors T1 to T3 may include either a silicon semiconductor or an oxide semiconductor. Here, the oxide semiconductor may include a crystalline or amorphous oxide semiconductor, and the silicon semiconductor may include amorphous silicon, polycrystalline silicon, or the like, but the present disclosure is not limited thereto.

Hereinafter, the first to third transistors T1 to T3 are described as N-type transistors, but the present disclosure is not limited thereto. Thus, each of the first to third transistors T1 to T3 may be a P-type transistor or an N-type transistor according to signals applied thereto. Here, a source and a drain of the P-type transistor may respectively correspond to a drain and a source of the N-type transistor.

FIG. 3 illustrates, as an example, the pixel PXij connected to an i-th scan line SCLi, an i-th sensing line SSLi, a j-th data line DLj, and a j-th initial line ILj.

The pixel circuit PC may include the first transistor T1 (e.g., a driving transistor), the second transistor T2 (e.g., a switching transistor), the third transistor T3 (e.g., a sensing transistor), and a capacitor Cst. However, the pixel circuit PC may further include an additional transistor and an additional capacitor, and is not limited to any one embodiment.

The light-emitting element OLED may be an inorganic light-emitting element or an organic light-emitting element including an anode (e.g., a first electrode) and a cathode (e.g., a second electrode). An anode of the light-emitting element OLED may receive a first voltage ELVDD through the first transistor T1, and a cathode of the light-emitting element OLED may receive a second voltage ELVSS. The light-emitting element OLED may emit light upon receiving the first voltage ELVDD and the second voltage ELVSS.

The first transistor T1 may include a drain D1 which receives the first voltage ELVDD, a source S1 which is connected to the anode of the light-emitting element OLED, and a gate G1 which is connected to the capacitor Cst. The first transistor T1 may control a drive current flowing through the light-emitting element OLED from the first voltage ELVDD in response to a voltage value stored in the capacitor Cst.

The second transistor T2 may include a drain D2 which is connected to the j-th data line DLj, a source S2 which is connected to the capacitor Cst, and a gate G2 which receives an i-th first scan signal SCi. The second transistor T2 provides a data voltage Vd to the first transistor T1 in response to the i-th first scan signal SCi.

The third transistor T3 may include a source S3 which is connected to the j-th initial line ILj, a drain D3 which is connected to the anode of the light-emitting element OLED, and a gate G3 which receives an i-th second scan signal SSi. The j-th initial line ILj may receive an initial voltage Vintit.

The capacitor Cst may store voltage differences of various values according to an input signal. For example, the capacitor Cst may store a voltage equivalent to a difference between a voltage transmitted from the second transistor T2 and the first voltage ELVDD.

As illustrated in FIG. 4, light generated from a first pixel PX-G may be provided to a first pixel region PXA-G, light generated from a second pixel PX-R may be provided to a second pixel region PXA-R, and light generated from a third pixel PX-B may be provided to a third pixel region PXA-B. The first to third pixel regions PXA-G, PXA-R, and PXA-B may correspond to openings PDL-OP defined in a pixel-defining film PDL to be described with reference to FIG. 5B.

A peripheral region NPXA is disposed between the first pixel region PXA-

G, the second pixel region PXA-R, and the third pixel region PXA-B. The peripheral region NPXA sets boundaries of the first to third pixel regions PXA-G, PXA-R, and PXA-B and prevent color mixing between the first to third pixel regions PXA-G, PXA-R, and PXA-B. According to one or more embodiments, the peripheral region NPXA may overlap a bank included in the light control layer OSL and including a light blocking material.

Each of the first to third pixels PX-G, PX-R, and PX-B may include a light-emitting element OLED-G (see FIG. 5B), and the first to third pixels PX-G, PX-R, and PX-B may generate source light of the same color. However, the present disclosure is not limited thereto, and light generated from the first to third pixels PX-G, PX-R, and PX-B may have different colors.

Source light generated from the light-emitting elements OLED-G (see FIG. 5B) of the first to third pixels PX-G, PX-R, and PX-B may be converted to any one color light from among red light, green light, and blue light through color control patterns included in the light control layer OSL described with reference to FIG. 2A. Converted light may be emitted through the first pixel region PXA-G, the second pixel region PXA-R, and the third pixel region PXA-B.

Referring to FIG. 4, the second pixel region PXA-R and the third pixel region PXA-B are disposed in the same row, and the first pixel region PXA-G is disposed in a row different from the row in which the second pixel region PXA-R and the third pixel region PXA-B are disposed. For example, the second pixel region PXA-R and the third pixel region PXA-B may be spaced from each other along a first direction DR1, and the first pixel region PXA-G may be spaced from the second pixel region PXA-R and the third pixel region PXA-B in respective diagonal directions of the first direction DR1 and a second direction DR2.

According to one or more embodiments, an area of the first pixel region PXA-G may be smaller than an area of the second pixel region PXA-R and greater than an area of the third pixel region PXA-B. However, in one or more other embodiments, an area of the first pixel region PXA-G may be greater than an area of the second pixel region PXA-R, which may be greater than an area of the third pixel region PXA-B.

In this embodiment, the first pixel region PXA-G, the second pixel region PXA-R, and the third pixel region PXA-B having square shapes are illustrated as examples, but an arrangement and areas of pixel regions are not limited thereto.

An arrangement structure of the first pixel region PXA-G, the second pixel region PXA-R, and the third pixel region PXA-B within a pixel unit PXU illustrated in FIG. 4 is merely one example, and the present disclosure is not limited thereto. In one or more embodiments, the first pixel region PXA-G, the second pixel region PXA-R, and the third pixel region PXA-B may be arranged along the first direction DR1 and disposed in the same row. In addition, arrangements of the first pixel region PXA-G, the second pixel region PXA-R, and the third pixel region PXA-B in respective pixel units PXU do not necessarily need to be the same.

FIG. 5A is a plan view illustrating that conductive patterns included in a pixel unit according to one or more embodiments of the present disclosure are stacked in a stacking order. FIG. 5B is a cross-sectional view taken along the line I-I′ in FIG. 5A.

Referring to FIG. 5A, one pixel unit PXU may include first to third pixels PX-G, PX-R, and PX-B. Each of the first to third pixels PX-G, PX-R, and PX-B may include the pixel circuit PC and the light-emitting element OLED described with reference to FIG. 3.

Each of the first to third pixels PX-G, PX-R, and PX-B is connected to a first power line ED, a second power line EL, an initial line IL, a scan line SCL, and a sensing line SSL. In addition, the first to third pixels PX-G, PX-R, and PX-B may be connected to corresponding data lines DL-G, DL-R, and DL-B. The first power line ED may provide the first voltage ELVDD (see FIG. 3), and the second power line EL may provide the second voltage ELVSS (see FIG. 3) which is lower than the first voltage ELVDD.

According to one or more embodiments, the data lines DL-G, DL-R, and DL-B, the initial line IL, and the second power line EL may be spaced from each other along a first direction DR1 and may each extend along a second direction DR2. The first power line ED, the scan line SCL, and the sensing line SSL may be spaced from each other along the second direction DR2 and may each extend along the first direction DR1. The first power line ED may be spaced from the sensing line SSL along the second direction DR2 with the scan line SCL therebetween. The pixel circuit PC (see FIG. 3) included in the first to third pixels PX-G, PX-R, and PX-B may be disposed between the sensing line SSL and the scan line SCL.

Referring to FIG. 5B, a display panel DP according to one or more embodiments includes a base layer BS, a circuit element layer DP-CL disposed on the base layer BS, a display element layer DP-OLED, an encapsulation layer TFE, a light control layer OSL, and a window panel WD.

The circuit element layer DP-CL is disposed on the base layer BS. The circuit element layer DP-CL may include insulating layers 10, 20, 30, 40, and 50 disposed on the base layer BS and conductive patterns EBR, BML-G, A2-G, B-P1, C-G2, SS-P, and DL-B disposed between the insulating layers 10, 20, 30, 40, and 50. According to one or more embodiments, each of first to fourth insulating layers 10, 20, 30, and 40 may be provided as an inorganic layer. The first to fourth insulating layers 10, 20, 30, and 40 may be provided as a single inorganic layer or multiple layers including inorganic layers different from each other, but are not limited to any one embodiment. A fifth insulating layer 50 may be provided as an organic layer.

For example, in the first insulating layer 10, inorganic layers including silicon nitride and silicon oxide may be stacked. The second insulating layer 20 may include a single inorganic layer of silicon oxide. The third insulating layer 30 may include a single inorganic layer containing silicon oxynitride. In the fourth insulating layer 40, inorganic layers including silicon nitride may be stacked. However, the present disclosure is not limited thereto, and a material and a layer structure of an inorganic layer included in the first to fourth insulating layers 10, 20, 30, and 40 may vary. The conductive patterns EBR, BML-G, A2-G, B-P1, C-G2, SS-P, and DL-B mentioned above will be described later.

A first light blocking pattern BML-G may be disposed on the base layer BS and may be connected to a source of a first transistor T1 included in a first pixel PX-G, receive a signal applied to the source, and form a sync structure below a semiconductor pattern. The first light blocking pattern BML-G may overlap a first semiconductor pattern and receive a bias voltage. The first light blocking pattern BML-G may also receive the first voltage ELVDD (see FIG. 3).

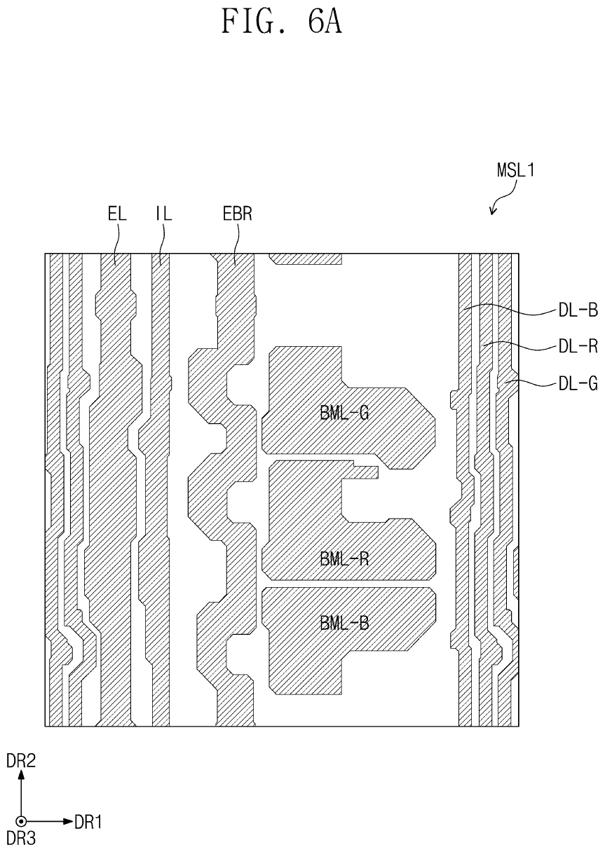

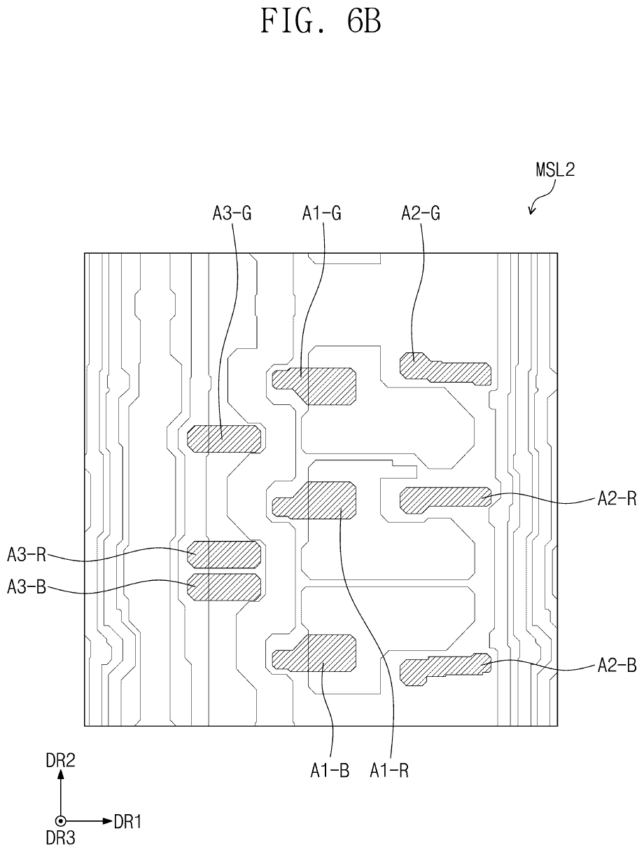

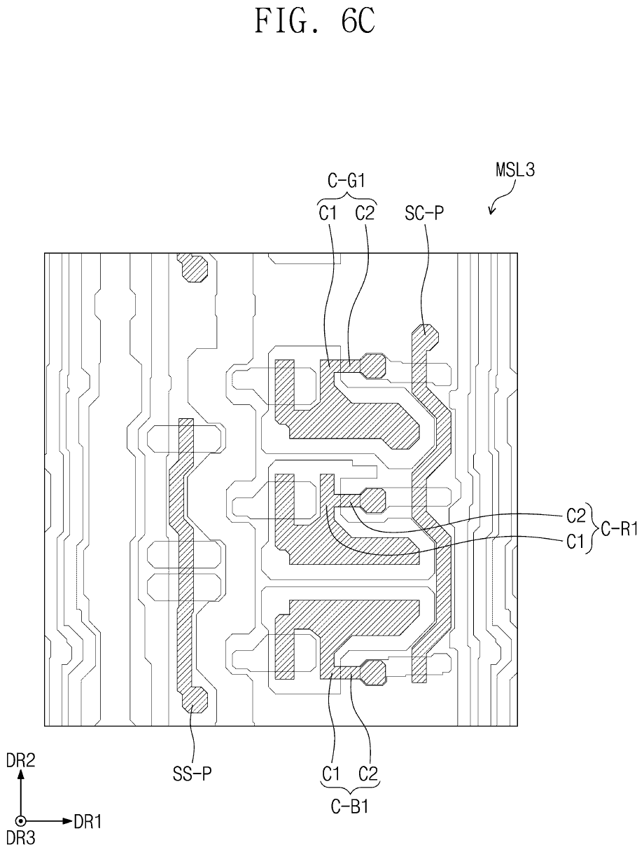

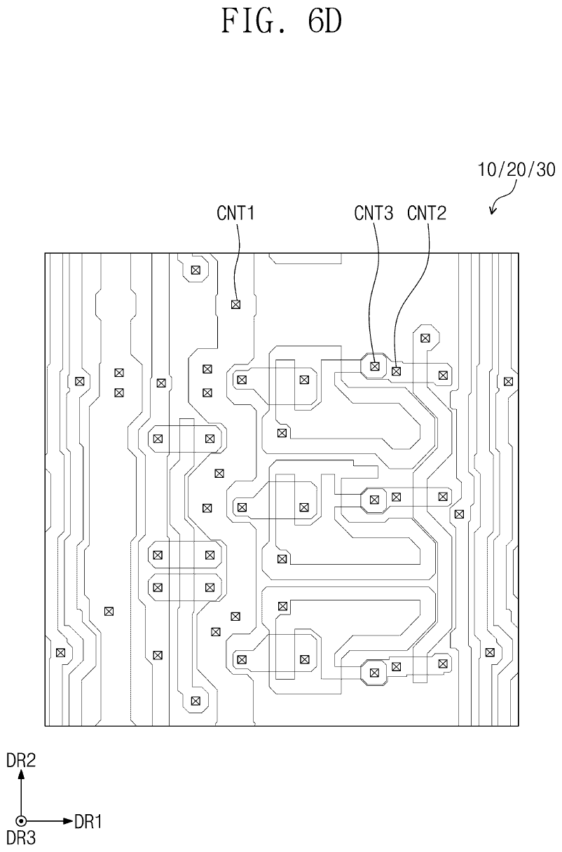

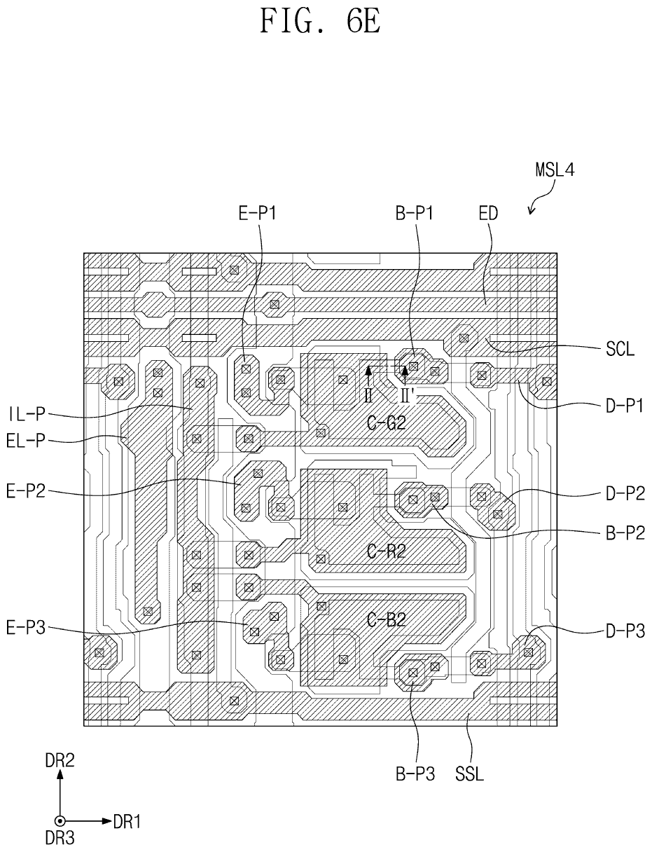

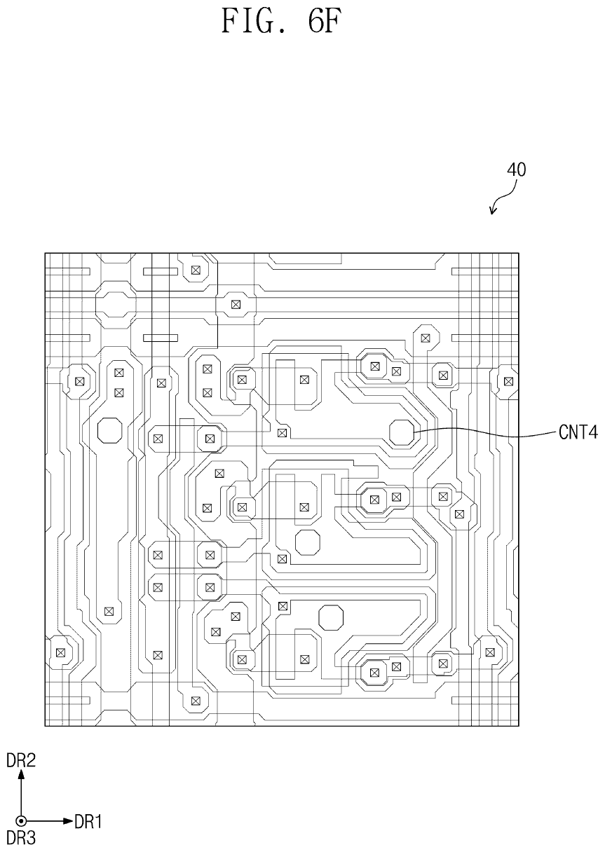

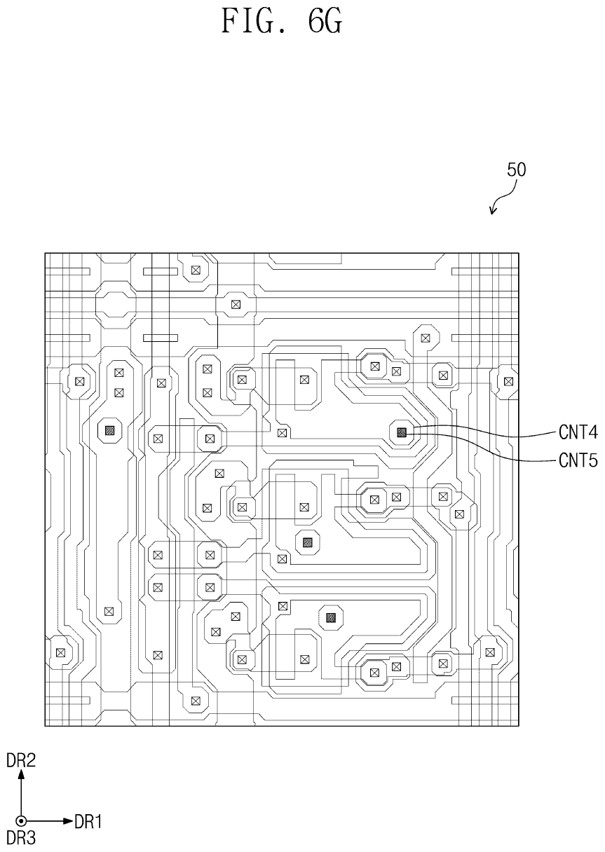

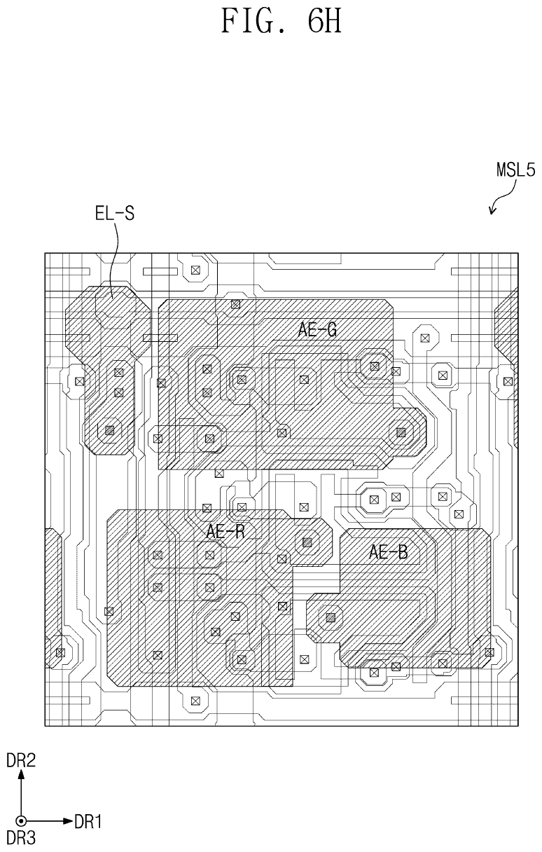

The first light blocking pattern BML-G may prevent electrical potential caused by polarization from affecting the first transistor T1. In addition, the first light blocking pattern BML-G may prevent external light from reaching the first transistor T1. In one or more embodiments, the first light blocking pattern BML-G may be a floating electrode isolated from another electrode or wiring. Description of the first blocking pattern BML-G may also be applied to second and third light blocking patterns BML-R and BML-B to be described with reference to FIG. 6A. The other conductive patterns will be described later in detail.

The display element layer DP-OLED may include a pixel-defining film PDL and a light-emitting element OLED-G. The pixel-defining film PDL may be disposed on the fifth insulating layer 50. The pixel-defining film PDL may include openings PDL-OP respectively corresponding to the pixel regions PXA-G, PXA-R, and PXA-B described with reference to FIG. 4. The light-emitting element OLED-G illustrated in FIG. 5B may be included in the first pixel PX-G described with reference to FIG. 4.

According to one or more embodiments, the pixel-defining film PDL may have a light-absorbing property, and for example, the pixel-defining film PDL may have a black color. The pixel-defining film PDL may include a black coloring agent. The black coloring agent may include a black dye and/or a black pigment. The black coloring agent may include carbon black, metal such as chromium, and/or oxides thereof. The pixel-defining film PDL may correspond to a light blocking pattern which has a light blocking property.

A first electrode AE-G of a first light-emitting element OLED-G may be disposed on the fifth insulating layer 50. A second electrode CE-G may be disposed on the first electrode AE-G. A common layer CL-G may be disposed between the first electrode AE-G and the second electrode CE-G. The common layer CL-G may include a light-emitting layer including an organic material, a hole control layer disposed between the first electrode AE-G and the light-emitting layer, and an electron control layer disposed between the light-emitting layer and the second electrode CE-G. The hole control layer may include a hole transport layer and a hole injection layer. The electron control layer may include an electron transport layer and an electron injection layer. According to one or more embodiments, the common layer CL-G and the second electrode CE-G may be common layers formed in common in first to third pixels PX-G, PX-R, and PX-B and may overlap pixel-defining film PDL. The pixel-defining film PDL may partially overlap the first electrode AE-G of a first light-emitting element OLED-G.

The encapsulation layer TFE may cover the display element layer DP-OLED. The encapsulation layer TFE may include an organic material or an inorganic material. The encapsulation layer TFE may have a multi-layered structure in which an inorganic layer/an organic layer are repeatedly stacked. In this embodiment, the encapsulation layer TFE may include a first inorganic layer, an organic layer, and a second inorganic layer, which are sequentially stacked. The first and second inorganic layers may protect a light-emitting element OLED from external moisture, and the organic layer may prevent dent defect of the light-emitting element OLED which may be caused by foreign substances introduced during a manufacturing process.

The first and second inorganic layers may each include at least one of silicon nitride, silicon oxynitride, silicon oxide, titanium oxide, and/or aluminum oxide. Each of the first and second inorganic layers may also have a multi-layered structure. The organic layer may include an acrylate-based organic layer, but the present disclosure is not limited thereto. The inorganic layers may protect the first light-emitting element OLED-G from moisture and oxygen, and the organic layer may protect the first light-emitting element OLED-G from foreign substances such as dust particles.

The light control layer OSL may be disposed on the encapsulation layer TFE. The light control layer OSL may be disposed between the encapsulation layer TFE and the window panel WD. A rear surface of the window panel WD may provide a base surface where components included in the light control layer OSL are formed. For convenience of description, the components included in the light control layer OSL will be described in an order in which the components are formed on the rear surface of the window panel WD.

A color filter layer CFL may be disposed on the rear surface of the window panel WD. The color filter layer CFL may include a first color filter CF1 that transmits first light, a second color filter CF2 that transmits second light, and a third color filter CF3 that transmits third light. In one or more embodiments, the first color filter CF1 may be a green filter, the second color filter CF2 may be a red filter, and the third color filter CF3 may be a blue filter.

Each of the first to third color filters CF1, CF2, and CF3 includes a polymer photosensitive resin and a colorant. The first color filter CF1 may include a green colorant, the second color filter CF2 may include a red colorant, and the third color filter CF3 may include a blue colorant. The first color filter CF1 may include a green pigment and/or green dye, the second color filter CF2 may include a red pigment and/or red dye, and the third color filter CF3 may include a blue pigment and/or blue dye.

The first color filter CF1 may overlap an opening PDL-OP corresponding to a first pixel region PXA-G, the second color filter CF2 may overlap an opening PDL-OP corresponding to a second pixel region PXA-R, and the third color filter CF3 may overlap an opening PDL-OP corresponding to a third pixel region PXA-B. In addition, the first to third color filters CF1, CF2, and CF3 may be disposed to respectively correspond to first to third light control patterns.

According to one or more embodiments, at least two color filters from among the first to third color filters CF1, CF2, and CF3 may overlap the pixel-defining film PDL. A plurality of color filters CF1, CF2, and CF3 may be disposed to overlap each other in a third direction DR3, that is a thickness direction of the base layer BS (e.g., a third direction DR3), to define a boundary between adjacent light-emitting regions. The color filters overlapping each other along the third direction DR3 may function to block light. Accordingly, it is possible to prevent colors of light passed through color control patterns from being mixed.

In one or more embodiments, the color filter layer CFL may include a light blocking portion to define a boundary between adjacent first to third color filters CF1, CF2, and CF3. The light blocking portion may be formed of a blue filter or may be formed while including an inorganic or organic light blocking material containing a black pigment and/or black dye.

A low refractive layer LR may be disposed between barrier layer CAP1 and the color filter layer CFL. In one or more embodiments, low refractive layer LR may be disposed between a first color control pattern and the color filter layer CFL. The low refractive layer LR may cover the first to third color filters CF1, CF2, and CF3.

The low refractive layer LR may include at least one inorganic layer. For example, the low refractive layer LR may include silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, and/or include a metal thin film having light transmittance, etc.

However, the present disclosure is not limited thereto, and the low refractive layer LR may include an organic film. The low refractive layer LR may have, for example, a structure in which a plurality of hollow particles are dispersed in an organic polymer resin. The low refractive layer LR may be composed of a single layer or a plurality of layers.

The low refractive layer LR may be covered by a barrier layer CAP1. According to one or more embodiments, the barrier layer CAP1 may be provided as multi-layered inorganic layers. The barrier layer CAP1 may prevent moisture/oxygen from infiltrating a color control layer CCP-G and improve film durability.

A bank BMP may be disposed below the barrier layer CAP1. The bank BMP may overlap the pixel-defining film PDL in the third direction DR3. The bank BMP may include a base resin and/or an additive. The base resin may be composed of various resin compositions which may be generally referred to as a binder. The additive may include a coupling agent and/or a photoinitiator. The additive may further include a dispersant. The bank BMP may include a black coloring agent for light blocking. The bank BMP may include a black pigment and/or black dye mixed in the base resin. In one or more embodiments, the black coloring agent may include carbon black, metal such as chromium, and/or oxides thereof.

The bank BMP includes a bank opening corresponding to an opening PDL-OP. A color control layer CCL-G may be disposed in the bank opening. The color control layer CCL-G may include quantum dots for changing an optical property of source light (e.g., source light generated from the light-emitting elements OLED-G). The color control layer CCL-G may include quantum dots for converting source light to light having a different wavelength. In the color control layer CCL-G, quantum dots may convert blue light that is source light to green light. According to one or more embodiments, a color control layer including quantum dots that convert blue source light to green light may be disposed in the bank opening overlapping the first color filter CF1.

An additional barrier layer CAP2 may cover the bank BMP and the color control layer CCL-G. The additional barrier layer CAP2 may be provided as an inorganic layer. Along with the barrier layer CAP1, the additional barrier layer CAP2 may encapsulate the bank BMP and color control layers. The additional barrier layer CAP2 and the barrier layer CAP1 may include the same material.

A filling layer FML may be disposed between the additional barrier layer CAP2 and the encapsulation layer TFE. The filling layer FML may function as a buffer between the display element layer DP-OLED and the light control layer OSL. In one or more embodiments, the filling layer FML may function to absorb impact, etc., and may raise the strength of the display panel DP. The filling layer FML may be formed from a filling resin including a polymer resin. For example, the filling layer FML may be formed from a filling layer resin including an acrylate-based resin, an epoxy-based resin, and/or the like.

The filling layer FML may be a component separate from the encapsulation layer TFE disposed thereunder and the additional barrier layer CAP2 disposed thereon, and thus the filling layer FML, the encapsulation layer TFE and the additional barrier layer CAP2 may be respectively formed through separate processing steps. The filling layer FML may be formed of a material different from those of the encapsulation layer TFE and the additional barrier layer CAP2.

FIGS. 6A-6I are plan views illustrating, for each layer, a stacking order of conductive patterns included in a pixel unit according to one or more embodiments of the present disclosure.

Referring to FIGS. 5A-6A, a first conductive layer MSL1 may be disposed on the base layer BS and covered by the first insulating layer 10. The first conductive layer MSL1 may include the second power line EL, the initial line IL, a power line EBR, first to third light blocking patterns BML-G, BML-R, and BML-B, and first to third data lines DL-G, DL-R, and DL-B.

The second power line EL, the initial line IL, the power line EBR, and the first to third data lines DL-G, DL-R, and DL-B may be spaced from each other along a first direction DR1 and may each extend along a second direction DR2. The initial line IL may be disposed between the second power line EL and the power line EBR. The second data line DL-R may be disposed between the first data line DL-G and the third data line DL-B.

The first to third light blocking patterns BML-G, BML-R, and BML-B may be spaced from each other along the second direction DR2. The first to third light blocking patterns BML-G, BML-R, and BML-B may be disposed between the power line EBR and the first to third data lines DL-G, DL-R, and DL-B.

Referring to FIGS. 5A-6B, a second conductive layer MSL2 may be disposed on the first insulating layer 10 and covered by the second insulating layer 20.

The second conductive layer MSL2 may include first to third semiconductor patterns A1-G, A2-G, and A3-G included in the first pixel PX-G, first to third semiconductor patterns A1-R, A2-R, and A3-R included in the second pixel PX-R, and first to third semiconductor patterns A1-B, A2-B, and A3-B included in the third pixel PX-B. The second semiconductor patterns A2-G, A2-R, and A2-B may not overlap the first to third light blocking patterns BML-G, BML-R, and BML-B.

Referring to FIGS. 5A-6C, a third conductive layer MSL3 may be disposed on the second insulating layer 20 and covered by the third insulating layer 30.

The third conductive layer MSL3 may include a sensing pattern SS-P, a scan pattern SC-P, and first to third lower capacitor patterns C-G1, C-R1, and C-B1. The sensing pattern SS-P may be a portion which is connected to a sensing line SSL (see FIG. 6E) to be described later and protrudes along a second direction DR2 from the sensing line SSL (see FIG. 6E). The scan pattern SC-P may be a portion which is connected to a scan line SCL (see FIG. 6E) to be described later and protrudes along the second direction DR2 from the scan line SCL (see FIG. 6E).

A portion, of the sensing pattern SS-P, overlapping the third semiconductor patterns A3-G, A3-R, and A3-B may be defined as a gate of the third transistor T3 (see FIG. 3). A portion, of the scan pattern SC-P, overlapping the second semiconductor patterns A2-G, A2-R, and A2-B may be defined as a gate of the second transistor T2 (see FIG. 3).

The first to third lower capacitor patterns C-G1, C-R1, and C-B1 may be spaced from each other along the second direction DR2. Each of the first to third lower capacitor patterns C-G1, C-R1, and C-B1 may include a first portion C1 and a second portion C2. The first portion C1 and the second portion C2 are substantially integrated with each other as a single pattern, but will be distinguished for convenience of description.

The first portion C1 may overlap corresponding first to third light blocking patterns BML-G, BML-R, and BML-B. The second portion C2 may protrude along a first direction DR1 from the first portion C1 and overlap corresponding second semiconductor patterns A2-G, A2-R, and A2-B.

A portion, of the first portion C1, overlapping corresponding first semiconductor patterns A1-G, A1-R, and A1-B may be defined as a gate of the first transistor T1 (see FIG. 3).

FIG. 6D illustrates contact holes defined by passing through at least one from among first to third insulating layers 10, 20, and 30.

First contact holes CNT1 may be defined by passing through the first to third insulating layers 10, 20, and 30. Conductive patterns of the first conductive layer MSL1 overlapping the first contact holes CNT1 may be connected to conductive patterns of a fourth conductive layer MSL4 (see FIG. 6E) through the first contact holes CNT1.

Second contact holes CNT2 may be defined by passing through the second and third insulating layers 20 and 30. Conductive patterns of the second conductive layer MSL2 overlapping the second contact holes CNT2 may be connected to conductive patterns of the fourth conductive layer MSL4 (see FIG. 6E) through the second contact holes CNT2.

Third contact holes CNT3 may be defined by passing through the third insulating layer 30. Conductive patterns of the third conductive layer MSL3 overlapping the third contact holes CNT3 may be connected to conductive patterns of the fourth conductive layer MSL4 (see FIG. 6E) through the third contact holes CNT3.

Referring to FIGS. 5A-6E, a fourth conductive layer MSL4 may be disposed on the third insulating layer 30 and covered by the fourth insulating layer 40.

The fourth conductive layer MSL4 may include the first power line ED, the scan line SCL, the sensing line SSL, a power pattern EL-P, an initial pattern IL-P, first to third power line patterns E-P1, E-P2, and E-P3, first to third upper capacitor patterns C-G2, C-R2, and C-B2, first to third bridge patterns B-P1, B-P2, and B-P3, and first to third data patterns D-P1, D-P2, and D-P3.

The first power line ED, the scan line SCL, and the sensing line SSL may be spaced from each other along a second direction DR2 and may each extend along a first direction DR1. According to this embodiment, the first power line ED may be disposed between the scan line SCL and the sensing line SSL. The pixel circuit PC described with reference to FIG. 3 may be disposed between the sensing line SSL and the scan line SCL. The scan line SCL may be connected to the scan pattern SC-P through the third contact hole CNT3, and the sensing line SSL may be connected to the sensing pattern SS-P through the third contact hole CNT3.

The power pattern EL-P may overlap the second power line EL and may be connected to the second power line EL through the first contact holes CNT1.

The initial pattern IL-P may overlap the initial line IL and may be connected to the initial line IL through the first contact holes CNT1.

The first to third power line patterns E-P1, E-P2, and E-P3 may overlap the power line EBR. The first to third power line patterns E-P1, E-P2, and E-P3 may be spaced from each other along the second direction DR2. The first to third power line patterns E-P1, E-P2, and E-P3 may be connected to the power line EBR through the first contact holes CNT1.

One end of the first power line pattern E-P1 may be connected to the power line EBR through the first contact holes CNT1, and the other end of the first power line pattern E-P1 may be connected to the first semiconductor pattern A1-G through the second contact hole CNT2.

One end of the second power line pattern E-P2 may be connected to the power line EBR through the first contact holes CNT1, and the other end of the second power line pattern E-P2 may be connected to the first semiconductor pattern A1-R through the second contact hole CNT2.

One end of the third power line pattern E-P3 may be connected to the power line EBR through the first contact holes CNT1, and the other end of the third power line pattern E-P3 may be connected to the first semiconductor pattern A1-B through the second contact hole CNT2.

The first to third upper capacitor patterns C-G2, C-R2, and C-B2 may overlap corresponding first to third lower capacitor patterns C-G1, C-R1, and C-B1. The first to third lower capacitor patterns C-G1, C-R1, and C-B1 and the first to third upper capacitor patterns C-G2, C-R2, and C-B2 may be connected to each other through the first contact hole CNT1. Lower and upper capacitor patterns overlapping each other may define the capacitor Cst described with reference to FIG. 3.

The first to third bridge patterns B-P1, B-P2, and B-P3 may connect the second semiconductor patterns A2-G, A2-R, and A2-B and the first to third lower capacitor patterns C-G1, C-R1, and C-B1.

One end of the first bridge pattern B-P1 may be connected to the second semiconductor pattern A2-G through the second contact hole CNT2, and the other end of the first bridge pattern B-P1 may be connected to a second portion C2 of the first lower capacitor pattern C-G1 through the third contact hole CNT3.

One end of the second bridge pattern B-P2 may be connected to the second semiconductor pattern A2-R through the second contact hole CNT2, and the other end of the second bridge pattern B-P2 may be connected to a second portion C2 of the second lower capacitor pattern C-R1 through the third contact hole CNT3.

One end of the third bridge pattern B-P3 may be connected to the second semiconductor pattern A2-B through the second contact hole CNT2, and the other end of the third bridge pattern B-P3 may be connected to a second portion C2 of the third lower capacitor pattern C-B1 through the third contact hole CNT3.

The first to third data patterns D-P1, D-P2, and D-P3 may connect the second semiconductor patterns A2-G, A2-R, and A2-B and the first to third data lines DL-G, DL-R, and DL-B.

One end of the first data pattern D-P1 may be connected to the first data line DL-G through the first contact hole CNT1, and the other end of the first data pattern D-P1 may be connected to the second semiconductor pattern A2-G through the second contact hole CNT2.

One end of the second data pattern D-P2 may be connected to the second data line DL-R through the first contact hole CNT1, and the other end of the second data pattern D-P2 may be connected to the second semiconductor pattern A2-R through the second contact hole CNT2.

One end of the third data pattern D-P3 may be connected to the second data line DL-R through the first contact hole CNT1, and the other end of the third data pattern D-P3 may be connected to the second semiconductor pattern A2-B through the second contact hole CNT2.

FIG. 6F illustrates fourth contact holes CNT4 defined by passing through a fourth insulating layer 40.

The fourth contact holes CNT4 may overlap the power pattern EL-P and the first to third upper capacitor patterns C-G2, C-R2, and C-B2.

FIG. 6G illustrates fifth contact holes CNT5 defined by passing through a fifth insulating layer 50.

The fifth contact holes CNT5 may overlap the power pattern EL-P and the first to third upper capacitor patterns C-G2, C-R2, and C-B2. The fifth contact holes CNT5 may overlap fourth contact holes CNT4. The fifth insulating layer 50 may be provided as an organic layer.

Referring to FIGS. 5A-6H, a fifth conductive layer MSL5 may be disposed on the fifth insulating layer 50 and covered by the pixel-defining film PDL.

The fifth conductive layer MSL5 may include first electrodes AE-G, AE-R, and AE-B respectively included in the pixels. The first electrodes AE-G, AE-R, and AE-B may be connected to first to third upper capacitor electrodes C-G2, C-R2, and C-B2 through corresponding fourth and fifth contact holes CNT4 and CNT5.

The fifth conductive layer MSL5 may further include an additional power pattern EL-S. The additional power pattern EL-S may be connected to the power pattern EL-P through corresponding fourth and fifth contact holes CNT4 and CNT5.

FIG. 6I illustrates the pixel-defining film PDL described with reference to FIG. 5B. For convenience of description, the openings PDL-OP described with reference to FIG. 5B are illustrated with dark hatching. The openings PDL-OP (see FIG. 5B) which expose at least a portion of each of the first electrodes AE-G, AE-R, and AE-B may be defined in the pixel-defining film PDL. The openings PDL-OP (see FIG. 5B) may correspond to first to third pixel regions PXA-G, PXA-R, and PXA-B. The first to third pixel regions PXA-G, PXA-R, and PXA-B may be regions to which source light generated from the first to third pixels PX-G, PX-R, and PX-B (see FIG. 5A) is provided.

An additional opening EL-OP which exposes at least a portion of the additional power pattern EL-S may be defined in the pixel-defining film PDL. The second electrode CE-G (see FIG. 5B) may be disposed in the additional opening EL-OP and connected to the second power line EL.

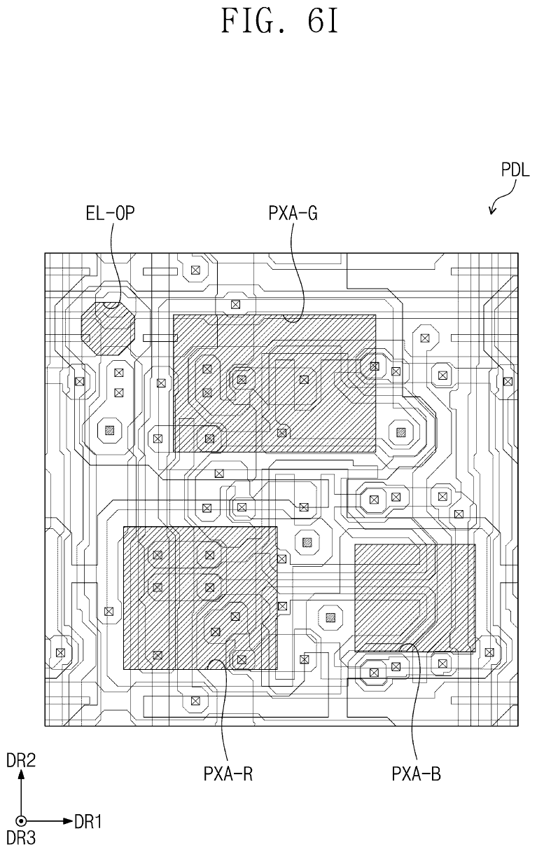

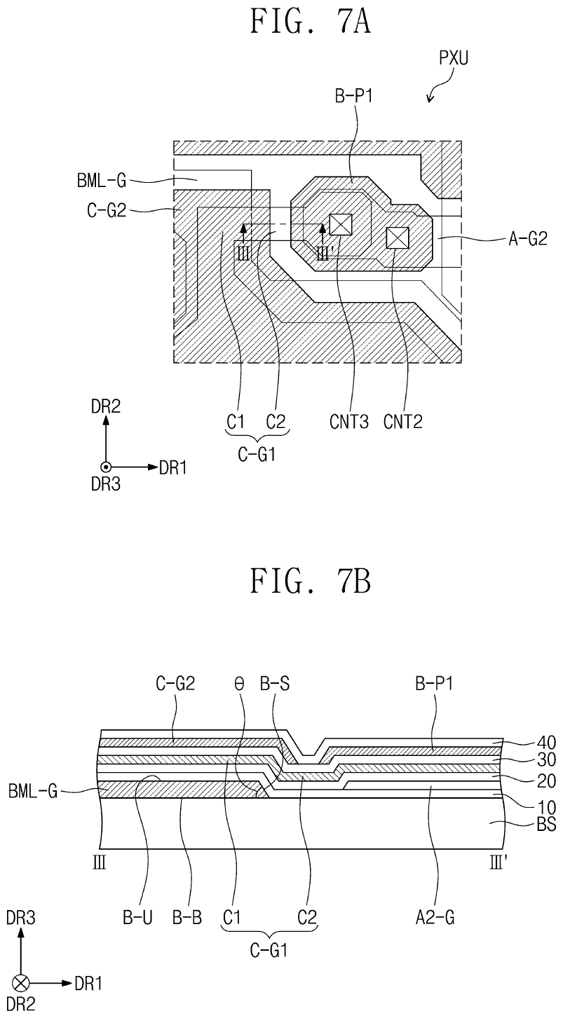

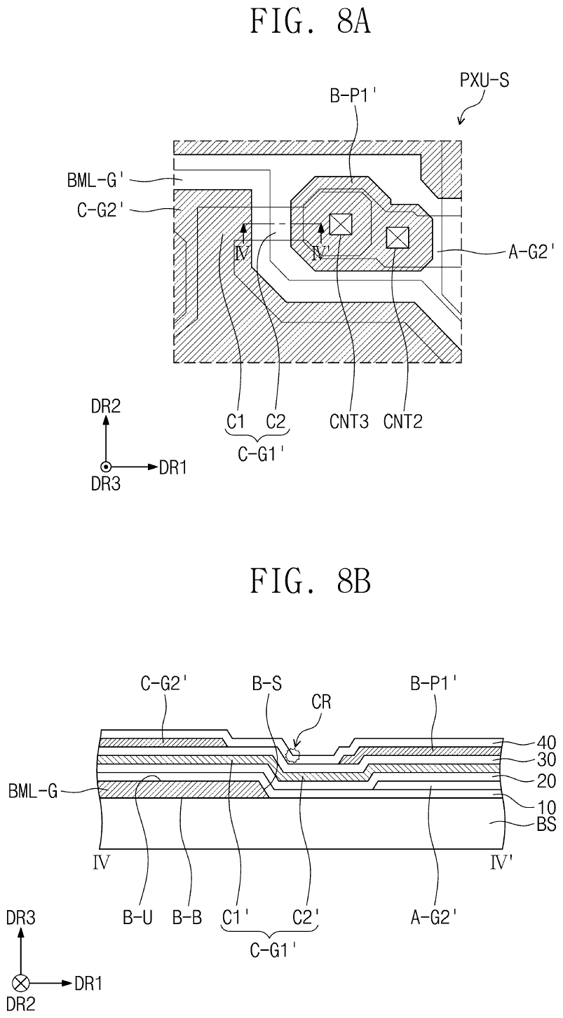

FIG. 7A is an enlarged plan view of one region of a pixel unit according to an embodiment of the inventive concept. FIG. 7B is a cross-sectional view taken along line II-II′ in FIG. 7A. FIG. 8A is a plan view of a comparative example. FIG. 8B is a cross-sectional view taken along line III-III′ in FIG. 8A.

FIG. 7A is an enlarged portion of the pixel unit PXU described with reference to FIG. 5A, and FIG. 8A illustrates a pixel unit PXU-S according to a comparative example which is different from the embodiments of the present disclosure, and illustrates the same region as that in FIG. 7A.

Referring to FIG. 7A and FIG. 7B, a first light blocking pattern BML-G according to one or more embodiments may include a lower surface B-B which is in contact with a base layer BS, an upper surface B-U which is opposed to the lower surface B-B, and a side surface B-S which connects the lower surface B-B and the upper surface B-U.

According to one or more embodiments, an angle Θ between the lower surface B-B and the side surface B-S may be about 60 degrees to about 80 degrees. The side surface B-S of the first light blocking pattern BML-G may have a predetermined angle Θ, and a crack may thus occur in some of insulating layers formed on the side surface B-S to overlap the side surface B-S.

A lower capacitor pattern C-G1 may include a first portion C1 overlapping the first light blocking pattern BML-G and a second portion C2 protruding from the first portion C-1 and overlapping a second semiconductor pattern A2-G in the third direction DR3.

An upper capacitor pattern C-G2 may be disposed on at least a portion of the first portion C1 and the second portion C2. A first bridge pattern B-P1 may overlap the second semiconductor pattern A2-G in the third direction DR3.

According to one or more embodiments, the upper capacitor pattern C-G2 may overlap the side surface B-S of the first light blocking pattern BML-G facing the second semiconductor pattern A2-G in a first direction DR1. That is, on a plane, the upper capacitor pattern C-G2 may protrude further than an outer side of the first light blocking pattern BML-G and cover the side surface B-S of the first light blocking pattern BML-G facing the second semiconductor pattern A2-G in the first direction DR1.

According one or more embodiments, a first insulating layer 10, a second insulating layer 20, the lower capacitor pattern C-G1, a third insulating layer 30, the upper capacitor pattern C-G2, and a fourth insulating layer 40 may be disposed on the side surface B-S. However, the present disclosure is not limited thereto, and at least one of the first to third insulating layers 10, 20, and/or 30 may be omitted.

The fourth insulating layer 40 disposed on the upper capacitor pattern C-G2 may be formed on the side surface B-S while having a relatively gentle slope in a region overlapping the side surface B-S due to the upper capacitor pattern C-G2.

Referring to FIG. 8A and FIG. 8B of a comparative example, an upper capacitor pattern C-G2′ in a comparative example may not overlap a side surface B-S of a first light blocking pattern BML-G′. That is, on a plane, the upper capacitor pattern C-G2′ may be disposed on an inner side of the first light blocking pattern BML-G′. Here, a first insulating layer 10, a second insulating layer 20, a lower capacitor pattern C-G1′, a third insulating layer 30, and a fourth insulating layer 40 may be disposed on the side surface B-S of the first light blocking pattern BML-G′.

The side surface B-S of the first light blocking pattern BML-G′ may have a slope, and a crack CR may thus occur in a region, of the fourth insulating layer 40, overlapping the side surface B-S. When the crack CR occurs in the fourth insulating layer 40, hydrogen included in an etchant may infiltrate a second semiconductor pattern A-G2′ and cause corrosion and a Vth negative shift of a transistor (e.g., negative shift of a threshold voltage of a transistor), and a bright spot may thus appear in an off-state of a display panel.

Referring back to FIG. 7A and FIG. 7B, the upper capacitor pattern C-G2 according to one or more embodiments may cover the side surface B-S of the first light blocking pattern BML-G facing the second semiconductor pattern A2-G in the first direction DR1. That is, because the fourth insulating layer 40 overlapping the side surface B-S may be disposed on the upper capacitor pattern C-G2, not on the third insulating layer 30, the upper capacitor pattern C-G2 may block an infiltration route of an etchant into the second semiconductor pattern A2-G even if a crack occurs in the fourth insulating layer 40. In addition, because the fourth insulating layer 40 overlapping the side surface B-S may be disposed on the upper capacitor pattern C-G2 and may thus be formed on the upper capacitor pattern C-G2 while having a relatively gentle slope, a crack may be prevented from occurring in the fourth insulating layer 40, compared to a case in which the fourth insulating layer 40 is formed directly on the third insulating layer 30.

Accordingly, a display panel DP according to one or more embodiments of the present disclosure may prevent and/or reduce a bright spot defect that may otherwise occur in an off-state of a display panel such as that of a comparative example. Thus, a display panel DP having improved display quality may be provided.

Description of the upper capacitor pattern C-G2 made above is made as one example and may be applied in common to the first to third pixels PX-G, PX-R, and PX-B described with reference to FIG. 5A. In addition, the fourth conductive layer MSL4 (see FIG. 6E) according to one or more embodiments may cover side surfaces of the light blocking patterns in a region as long as the region is where the fourth insulating layer 40 is formed and the light blocking patterns face the semiconductor patterns.

According to one or more embodiments of the present disclosure, an upper capacitor pattern may cover a side surface of a light blocking pattern, thereby preventing corrosion of a semiconductor pattern and alleviating bright spot occurrence in an off-state of a display panel. Thus, a display panel having improved display quality may be provided.

Although the embodiments of the present disclosure have been described, it is understood that the present disclosure is not limited to these embodiments, and various changes and modifications may be made by one ordinary skilled in the art within the spirit and scope of the present disclosure as hereinafter claimed.

Therefore, the technical scope of the present disclosure is not limited to the embodiments described in here, but may be defined by the accompanying claims and their equivalents.

What is claimed is:

1. A display panel comprising:
a base layer;
a light blocking pattern on the base layer;
a semiconductor pattern not overlapping the light blocking pattern;
a lower capacitor pattern comprising a first portion overlapping the light blocking pattern and a second portion protruding in a first direction from the first portion and overlapping the semiconductor pattern;
an upper capacitor pattern overlapping the lower capacitor pattern; and
a light-emitting element connected to the semiconductor pattern,
wherein the light blocking pattern includes a lower surface facing the base layer, an upper surface opposed to the lower surface, and a side surface connecting the lower surface and the upper surface, and
wherein the upper capacitor pattern overlaps the side surface facing the semiconductor pattern in the first direction.

2. The display panel of claim 1, wherein an angle between the lower surface and the side surface of the light blocking pattern is about 60 degrees to about 80 degrees.

3. The display panel of claim 1, comprising:
a first insulating layer on the base layer and covering the light blocking pattern;
a second insulating layer on the first insulating layer and covering the semiconductor pattern;
a third insulating layer on the second insulating layer and covering the lower capacitor pattern;
a fourth insulating layer on the third insulating layer and covering the upper capacitor pattern; and
a fifth insulating layer on the fourth insulating layer and comprising an organic material.

4. The display panel of claim 3, further comprising a bridge pattern overlapping the semiconductor pattern and the second portion of the lower capacitor pattern,
wherein one end of the bridge pattern is connected to the semiconductor pattern through a first contact hole passing through the second and third insulating layers, and an other end of the bridge pattern is connected to the second portion of the lower capacitor pattern through a second contact hole passing through the third insulating layer.

5. The display panel of claim 3, wherein the first insulating layer, the second insulating layer, the lower capacitor pattern, the third insulating layer, the upper capacitor pattern, and the fourth insulating layer are on the side surface of the light blocking pattern facing the semiconductor pattern in the first direction.

6. The display panel of claim 5, wherein a portion, of the upper capacitor pattern, overlapping the side surface of the light blocking pattern facing the semiconductor pattern in the first direction, is inclined at an angle corresponding to an inclined angle of the side surface.

7. The display panel of claim 3, comprising a first power line, a scan line, a sensing line, which extend along the first direction and are spaced from each other along a second direction crossing the first direction, and a data line which extends along the second direction,
wherein the light blocking pattern is located between the scan line and the sensing line.

8. The display panel of claim 7, wherein the scan line further comprises a scan pattern protruding in the second direction, and
wherein the scan pattern overlaps the semiconductor pattern.

9. The display panel of claim 8, wherein a portion of the scan pattern overlapping the semiconductor pattern comprises a gate of a transistor comprising the semiconductor pattern.

10. The display panel of claim 9, wherein the scan pattern is on the second insulating layer and covered by the third insulating layer, and
a portion of the scan pattern is connected to the scan line through a contact hole in the third insulating layer.

11. The display panel of claim 7, further comprising a data pattern having one end overlapping the semiconductor pattern and an other end overlapping the data line,
wherein the one end of the data pattern is connected to the semiconductor pattern through a third contact hole passing through the second and third insulating layers, and the other end of the data pattern is connected to the data line through a fourth contact hole passing through the first to third insulating layers.

12. The display panel of claim 3, wherein the light-emitting element comprises a first electrode on the fifth insulating layer, a second electrode, and a common layer located between the first electrode and the second electrode, and
wherein the first electrode is connected to the upper capacitor pattern through a fifth contact hole passing through the fourth insulating layer and a sixth contact hole passing through the fifth insulating layer and overlapping the fifth contact hole.

13. The display panel of claim 1, further comprising an encapsulation layer on the light-emitting element and comprising inorganic layers and an organic layer between the inorganic layers.

14. The display panel of claim 13, further comprising a light control layer on the encapsulation layer and comprising a color control pattern comprising quantum dots and a color filter pattern on the color control pattern.

15. A display panel comprising:
a base layer;
a light blocking pattern on the base layer;
a data line spaced from the light blocking pattern along a first direction and extending along a second direction crossing the first direction;
a capacitor comprising a lower capacitor pattern overlapping the light blocking pattern and an upper capacitor pattern overlapping the lower capacitor pattern; and
a pixel comprising a light-emitting element, a first transistor, a second transistor, and a third transistor, each of the first to third transistors comprising a semiconductor pattern,
wherein the semiconductor pattern in the second transistor is connected to the data line, and
wherein a side surface of the light blocking pattern facing the semiconductor pattern in the second transistor in the first direction is covered by the upper capacitor pattern.

16. The display panel of claim 15, wherein an angle between the base layer and the side surface of the light blocking pattern is about 60 degrees to about 80 degrees.

17. The display panel of claim 15, further comprising a first power line, a scan line, and a sensing line, which extend along the first direction and spaced from each other along the second direction crossing the first direction, and an initial line which extends along the second direction,
wherein the light blocking pattern is located between the scan line and the sensing line.

18. The display panel of claim 17, wherein the semiconductor pattern in the first transistor is connected to the first power line.

19. The display panel of claim 18, wherein the semiconductor pattern in the third transistor is connected to the initial line.

20. The display panel of claim 18, wherein a portion, of the upper capacitor pattern, overlapping the side surface of the light blocking pattern, is inclined at a predetermined angle.
